(19) United States
(12) Patent Application Publication
(10) Pub. No.: US 2024/0194397 A1
(43) Pub. Date: Jun. 13, 2024

(54) INDUCTOR COMPONENT

(71) Applicant: Murata Manufacturing Co., Ltd., Kyoto-fu (JP)

(72) Inventors: Kenichi TANI, Nagaokakyo-shi (JP); Yuuichirou YOSHIDA, Nagaokakyo-shi (JP)

(73) Assignee: Murata Manufacturing Co., Ltd., Kyoto-fu (JP)

(21) Appl. No.: 18/534,896

(22) Filed: Dec. 11, 2023

(30) Foreign Application Priority Data
Dec. 12, 2022 (JP) 2022-197923

(51) Int. Cl. H01F 27/29; H01F 27/28

(52) U.S. Cl. CPC H01F 27/292; H01F 27/2804; H01F 2027/2809

(57) ABSTRACT

An inductor component includes a body, a coil, and first and second outer electrodes. The coil is in the body and is helically wound around an axis. The first outer electrode and the second outer electrode are at the body and are electrically connected to the coil. The first outer electrode includes a first end face portion extending along a first end face of the body and a first bottom face portion connected to the first end face portion and extending along a bottom face of the body. The second outer electrode includes a second end face portion extending along a second end face of the body and a second bottom face portion connected to the second end face portion and extending along the bottom face. The axis is parallel to the bottom face and forms an angle with respect to first and second side faces of the body.

### CROSS-REFERENCE TO RELATED APPLICATION

This application claims benefit of priority to Japanese Patent Application No. 2022-197923, filed Dec. 12, 2022, the entire content of which is incorporated herein by reference.

### BACKGROUND

### Technical Field

The present disclosure relates to an inductor component.

### Background Art

Inductor components known in the art include the one disclosed in Japanese Unexamined Patent Application Publication No. 2017-92447. The inductor component includes a body, a coil, a first outer electrode, and a second outer electrode. The coil is disposed in the body and is helically wound around an axis. The first outer electrode and the second outer electrode are provided to the body and are electrically connected to the coil. The first outer electrode and the second outer electrode are each L-shaped. The coil is rectangular in shape and is disposed between the first outer electrode and the second outer electrode when viewed in the axial direction.

### SUMMARY

The first outer electrode and the second outer electrode of the inductor component known in the art constitute a constraint on the inner diameter of the coil disposed between the first outer electrode and the second outer electrode when viewed in the axial direction. It has been therefore difficult to increase the inner diameter of the coil with a view to improving the inductance characteristics and Q characteristics.

Accordingly, the present disclosure provides an inductor component with improved inductance characteristics and improved Q characteristics.

An inductor component according to an aspect of the present disclosure includes a body; a coil disposed in the body and helically wound around an axis; a first outer electrode and a second outer electrode that are provided to the body and electrically connected to the coil. The body has a first end face and a second end face on opposite sides, a first side face and a second side face on opposite sides, a bottom face connected between the first end face and the second end face and between the first side face and the second side face, and a top face on an opposite side from the bottom face. The first outer electrode includes a first end face portion extending along the first end face and a first bottom face portion connected to the first end face portion and extending along the bottom face. The second outer electrode includes a second end face portion extending along the second end face and a second bottom face portion connected to the second end face portion and extending along the bottom face. The axis is parallel to the bottom face and forms an angle with respect to the first side face and the second side face. The coil viewed in a direction of the axis includes a first section facing the top face, a second section facing the first end face, a third section facing the first end face portion, a fourth section facing the first bottom face portion, a fifth section facing the bottom face, a sixth section facing the second bottom face portion, a seventh section facing the second end face portion, and an eighth section facing the second end face. The first section, the second section, the third section, the fourth section, the fifth section, the sixth section, the seventh section, and the eighth section are arranged in sequence in a circular fashion when viewed in the direction of the axis. The second section is closer than the third section to the first end face when viewed in the direction of the axis. The eighth section is closer than the seventh section to the second end face when viewed in the direction of the axis. The fifth section is closer than the fourth section and the sixth section to the bottom face when viewed in the direction of the axis.

The features involved are as follows. The second section is closer than the third section to the first end face; the eighth section is closer than the seventh section to the second end face; and the fifth section is closer than the fourth section and the sixth section to the bottom face. The second section, the fifth section, and the eighth section, that is, the sections facing neither the first outer electrode nor the second outer electrode are spaced apart in the radial direction of the coil. This means that the coil is stretched out into regions being part of the body and not being subject to interference from the first outer electrode and the second outer electrode. The increase in the inner diameter of the coil yields an improvement in inductance characteristics and an improvement in Q characteristics.

The inductor component according to an aspect of the present disclosure can exhibit improved inductance characteristics and improved Q characteristics.

### BRIEF DESCRIPTION OF THE DRAWINGS

FIG. 1 is a perspective view of an inductor component according to a first embodiment;

FIG. 2 is a front view of the inductor component seen through a first side face of the inductor component;

FIG. 3A is one part of an exploded plan view of the inductor component;

FIG. 3B is the other part of the exploded plan view of the inductor component;

FIG. 4 is another front view of the inductor component seen through the first side face; and

FIG. 5 is an enlarged front view of part of an inductor component according to a second embodiment, with the inductor component seen through a first side face of the inductor component.

### DETAILED DESCRIPTION

Hereinafter, an inductor component according to an aspect of the present disclosure is described in detail by way of embodiments with reference to the accompanying drawings. The drawings may be partially schematic; that is, the drawings are not necessarily dimensionally accurate and are not necessarily drawn to scale.

### First Embodiment

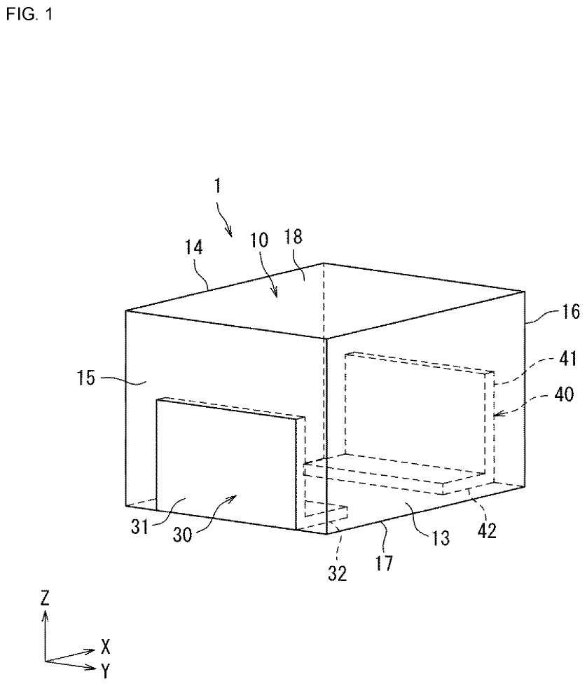

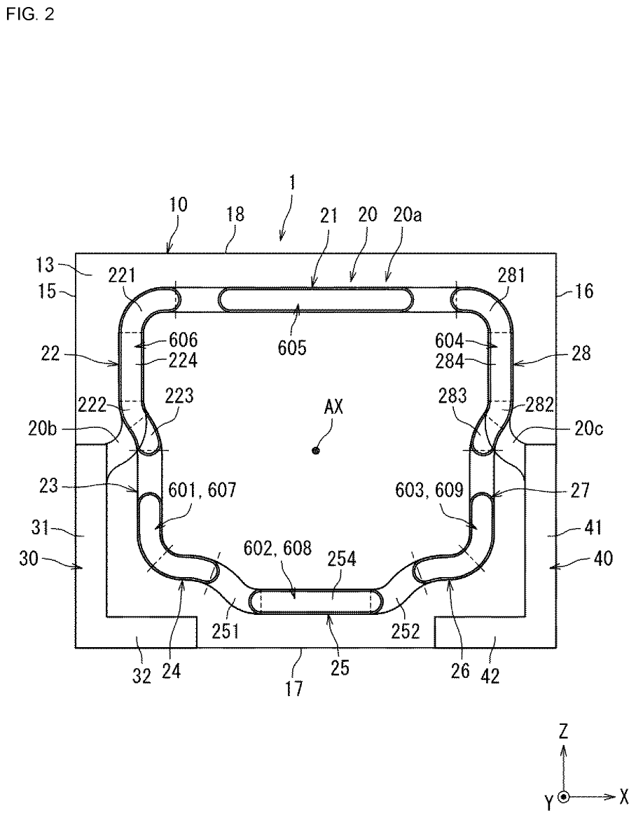

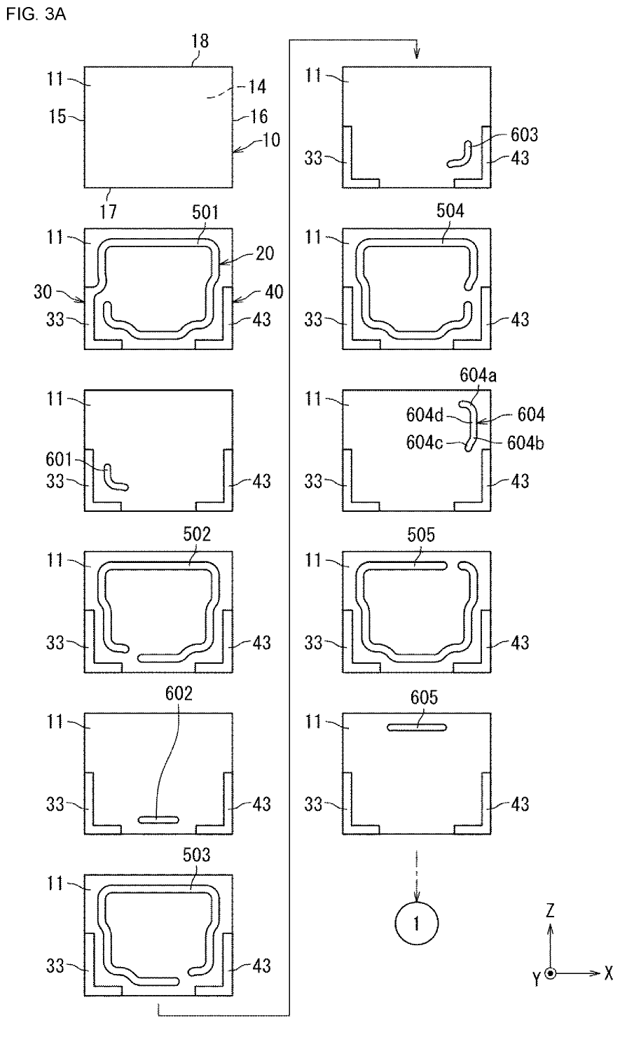

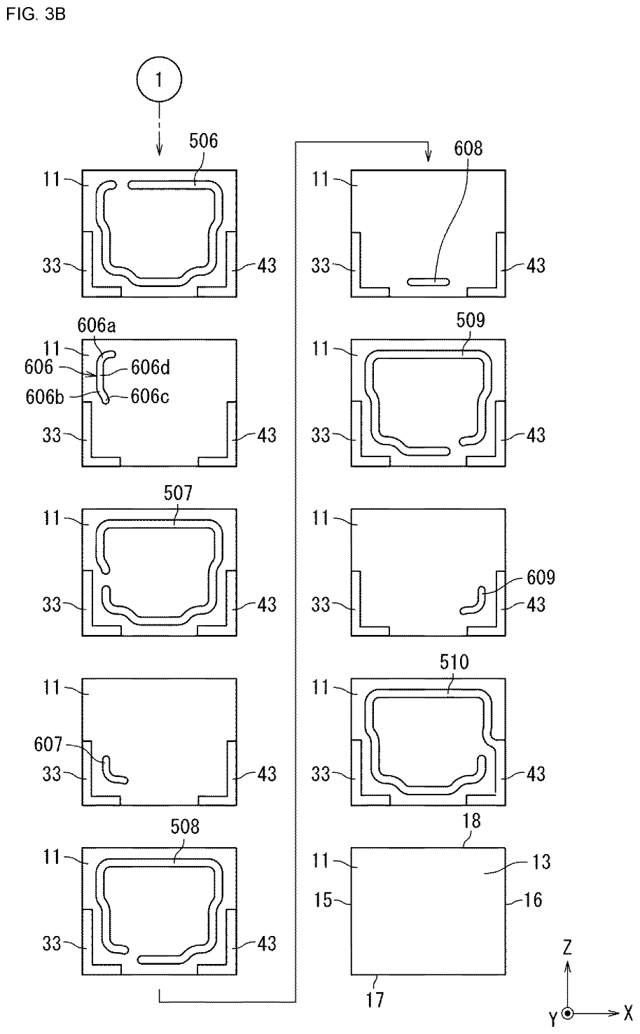

FIG. 1 is a perspective view of an inductor component according to a first embodiment. FIG. 2 is a front view of the inductor component seen through a first side face of the inductor component. FIGS. 3A and 3B are each part of an exploded plan view of the inductor component. Referring to FIGS. 1, 2, 3A, and 3B, an inductor component 1 includes a body 10, a coil 20, a first outer electrode 30, and a second outer electrode 40. The coil 20 is disposed in the body 10 and is helically wound around an AX. The first outer electrode 30 and the second outer electrode 40 are provided to the body 10 and are electrically connected to the coil 20. Although FIG. 2 illustrates a transparent body and a transparent coil for the purpose of facilitating the understanding of the structure, the body and the coil may be translucent or opaque.

The inductor component 1 is electrically connected to wiring of a circuit board (not illustrated) with the first outer electrode 30 and the second outer electrode 40 disposed therebetween. For example, the inductor component 1 is used as an impedance matching coil (i.e., a matching coil) for a radio-frequency circuit and may be included in an electronic device, such as a personal computer, a DVD player, a digital camera, a TV, a mobile phone, automobile electronics, or a medical/industrial device. The range of uses is not limited to the above. The inductor component 1 may be used as, for example, a tuned circuit, a filter circuit, or a rectifying/smoothing circuit.

The body 10 is substantially a rectangular parallelepiped. The surface of the body 10 includes a first end face 15, a second end face 16, a first side face 13, a second side face 14, a bottom face 17, and a top face 18. The first end face 15 and the second end face 16 are located on opposite sides. The first side face 13 and the second side face 14 are located on opposite sides. The bottom face 17 is connected between the first end face 15 and the second end face 16 and between the first side face 13 and the second side face 14. The top face 18 is located on the opposite side from the bottom face 17. The inductor component 1 is to be mounted onto a mounting substrate (not illustrated), with the bottom face 17 being oriented toward the mounting substrate.

As can be seen in the accompanying drawings, X denotes a direction orthogonal to the first end face 15 and the second end face 16 and pointing from the first end face 15 to the second end face 16. Y denotes a direction orthogonal to the first side face 13 and the second side face 14 and pointing from the second side face 14 to the first side face 13. Z denotes a direction orthogonal to the bottom face 17 and the top face 18 and pointing from the bottom face 17 to the top face 18. The X direction, the Y direction, and the Z direction may be hereinafter also referred to as a length direction, a width direction, and a height direction, respectively, of the body 10. The X direction, the Y direction, and the Z direction are orthogonal to one another. With three axes in the order X-Y-Z, the X, Y, and Z directions form a left-handed coordinate system.

The body 10 includes insulating layers 11, which are stacked on top of one another. The insulating layers 11 are made of, for example, a material containing borosilicate glass as a principal component, ferrite, or resin. The insulating layers 11 are stacked in a direction (the Y direction) parallel to the first end face 15, the second end face 16, and the bottom face 17 of the body 10. That is, the insulating layers 11 arranged in a stack each extend in an X-Z plane. The term “parallel” implies not only the state of being parallel in a strict sense but also the state of being substantially parallel in view of actual variations. The insulating layers 11 arranged in a stack are fired to obtain the body 10, in which the interface between the insulating layers 11 is thus not necessarily clear. Referring to FIGS. 3A and 3B, the direction pointing from the top to bottom coincides with the direction (the Y direction) in which the insulating layer 11 are stacked.

The first outer electrode 30 and the second outer electrode 40 are made of a conductive material, such as Ag, Cu, Au, or an alloy containing any one of these metals as a principal component. The first outer electrode 30 is an L-shaped electrode extending along the first end face 15 and the bottom face 17. The first outer electrode 30 is embedded in the body 10 and exposed at the first end face 15 and the bottom face 17. The first outer electrode 30 includes a first end face portion 31 and a first bottom face portion 32. The first end face portion 31 extends along the first end face 15, and the first bottom face portion 32 is connected to the first end face portion 31 and extends along the bottom face 17.

The second outer electrode 40 is an L-shaped electrode extending along the second end face 16 and the bottom face 17. The second outer electrode 40 is embedded in the body 10 and exposed at the second end face 16 and the bottom face 17. The second outer electrode 40 includes a second end face portion 41 and a second bottom face portion 42. The second end face portion 41 extends along the second end face 16, and the second bottom face portion 42 is connected to the second end face portion 41 and extends along the bottom face 17.

The first outer electrode 30 includes first outer electrode conductor layers 33, which are embedded in the body 10 (the respective insulating layers 11) and stacked on top of one another. The second outer electrode 40 includes second outer electrode conductor layers 43, which are embedded in the body 10 (the respective insulating layers 11) and stacked on top of one another. The first outer electrode conductor layers 33 each extend along the first end face 15 and the bottom face 17, and the second outer electrode conductor layers 43 each extend along the second end face 16 and the bottom face 17.

The inductor component including the first outer electrode 30 and the second outer electrode 40 embedded in the body 10 may be more compact in size than if the outer electrodes are externally added to the body 10. The coil 20 and the outer electrodes 30 and 40 can be formed in one process step such that the variations in the positional relationship between the coil 20 and the outer electrodes 30 and 40 is reduced. The unevenness in the electrical characteristics of the inductor component 1 can be reduced accordingly.

The coil 20 is made of a conductive material, examples of which include those mentioned above as the material of the first outer electrode 30 and the second outer electrode 40. The coil 20 is helically wound around an axis extending in the direction in which the insulating layers 11 are stacked. The coil 20 has a first end connected to the first outer electrode 30 and a second end connected to the second outer electrode 40. The coil 20, the first outer electrode 30, and the second outer electrode 40 in the present embodiment are combined into one piece with no clear boundaries therebetween. In some embodiments, however, the coil 20 and each of the first and second outer electrodes may be made of different materials or may be made by means of different methods, in which case there may be a boundary between the coil and each of the first and second outer electrodes.

The axis AX around which the coil 20 is wound is parallel to the bottom face 17 and forms an angle with respect to the first side face 13 and the second side face 14. The direction of the axis AX of the coil 20 coincides with the direction (the Y direction) in which the insulating layers 11 are stacked. The axis AX of the coil 20 is the central axis of a helical structure of the coil 20.

The coil 20 includes a winding portion 20a, a first extended portion 20b, and a second extended portion 20c. The first extended portion 20b is connected between a first end of the winding portion 20a and the first outer electrode 30. The second extended portion 20c is connected between a second end of the winding portion 20a and the second outer electrode 40. The winding portion 20a, the first extended portion 20b, and the second extended portion 20c in the present embodiment are combined into one piece with no clear boundaries therebetween. In some embodiments, however, the winding portion and each of the first and second extended portions may be made of different materials or may be made by means of different methods, in which case there may be a boundary between the winding portion and each of the first and second extended portions.

The winding portion 20a is helically wound around the axis AX. That is, the winding portion 20a is a helix consisting of overlapping regions of the coil 20 when viewed in a direction parallel to the axis AX. The first extended portion 20b and the second extended portion 20c are located outside the overlapping regions.

Referring to FIG. 2, the coil 20 includes a first section 21, a second section 22, a third section 23, a fourth section 24, a fifth section 25, a sixth section 26, a seventh section 27, and an eighth section when viewed in the direction of the axis AX of the coil 20. The first section 21 faces the top face 18. The second section 22 faces the first end face 15. The third section 23 faces the first end face portion 31. The fourth section 24 faces the first bottom face portion 32. The fifth section 25 faces the bottom face 17. The sixth section 26 faces the second bottom face portion 42. The seventh section 27 faces the second end face portion 41. The eighth section 28 faces the second end face 16. Unless otherwise noted, the boundaries between the sections (the first section 21 to the eighth section 28) correspond to the boundaries between the faces 15, 16, 17, and 18 and between the portions 31, 32, 41, and 42 and are specifically indicated by dash-dot lines in FIG. 2.

The first section 21, the second section, 22 the third section 23, the fourth section 24, the fifth section 25, the sixth section 26, the seventh section 27, and the eighth section 28 are arranged in sequence in a circular fashion. The first section 21 to the eighth section 28 in the present embodiment are arranged counterclockwise.

The second section 22 is closer than the third section 23 to the first end face 15. That is, the proportion of the region close to the first end face 15 is greater in the second section 22 than in the third section 23. Likewise, the eighth section 28 is closer than the seventh section 27 to the second end face 16. That is, the proportion of the region close to the second end face 16 is greater in the eighth section 28 than in the seventh section 27. Likewise, the fifth section 25 is closer than the fourth section 24 and the sixth section 26 to the bottom face 17. That is, the proportion of the region close to the bottom face 17 is greater in the fifth section 25 than in the fourth section 24 and in the sixth section 26.

The features involved are as follows: the second section 22 is closer than the third section 23 to the first end face 15; the eighth section 28 is closer than the seventh section 27 to the second end face 16; and the fifth section 25 is closer than the fourth section 24 and the sixth section 26 to the bottom face 17. That is, the second section 22, the fifth section 25, and the eighth section 28, which face neither the first outer electrode 30 nor the second outer electrode 40, are spaced apart in the radial direction of the coil 20. This means that the coil 20 is stretched out into regions being part of the body 10 and not being subject to interference from the first outer electrode 30 and the second outer electrode 40. The increase in the inner diameter of the coil 20 yields an improvement in inductance characteristics and an improvement in Q characteristics.

Despite the increase in the inner diameter, the coil 20 interferes with neither the first outer electrode 30 nor the second outer electrode 40. This eliminates the need to increase the size of the body 10. Accordingly, the body 10 can be more compact in size.

Referring to FIG. 2, the first section 21, the third section 23, the fifth section 25, and the seventh section 27 each include a linear portion when viewed in the direction of the axis AX of the coil 20. The first section 21, the third section 23, the fifth section 25, and the seventh section 27 are thus easier to produce. The inductor component 1 can thus be produced in such a way as to reduce inter-component variability.

More specifically, the first section 21 includes a linear portion parallel to the top face 18. The linear portion of the first section 21 has a first end connected to the second section 22 and a second end connected to the eighth section 28.

The third section 23 includes a linear portion parallel to the first end face portion 31. The linear portion of the third section 23 has a first end connected to the second section 22 and a second end connected to the fourth section 24.

The seventh section 27 includes a linear portion parallel to the second end face portion 41. The linear portion of the seventh section 27 has a first end connected to the sixth section 26 and a second end connected to the eighth section 28.

The fifth section 25 includes a linear portion 254, a first curved portion 251, and a second curved portion 252. The linear portion 254 is parallel to the bottom face 17. The first curved portion 251 is connected between a first end of the linear portion 254 and the fourth section 24. The second curved portion 252 is connected between a second end of the linear portion 254 and the sixth section 26. The first curved portion 251 and the second curved portion 252 are each curved outward in the radial direction of the coil 20. The junction between the first curved portion 251 and the fourth section 24 and the junction between the second curved portion 252 and the sixth section 26 are each curved inward in the radial direction of the coil 20. Each curved part is shaped into, for example, a circular arc. The boundary between the first curved portion 251 and the linear portion 254 and the boundary between the second curved portion 252 and the linear portion 254 are indicated by dotted lines in FIG. 2.

As illustrated in FIG. 2, the fourth section 24 and the sixth section 26 are curved when viewed in the direction of the axis AX of the coil 20. The expression “be curved” is herein used to describe a state in which the section of interest includes at least one curved part and no linear portion. Although thermal stress and/or bending stress can be exerted on the inductor component 1 during mounting, the fourth section 24 and the sixth section 26 each including no linear portion can escape undue stress.

Specifically, the junction between the fourth section 24 and the fifth section 25 is curved inward in the radial direction of the coil 20. The junction between the fourth section 24 and the third section 23 is curved outward in the radial direction of the coil 20. The fourth section 24 is curved and extends between the two curved junctions.

The junction between the sixth section 26 and the fifth section 25 is curved inward in the radial direction of the coil 20. The junction between the sixth section 26 and the seventh section 27 is curved outward in the radial direction of the coil 20. The sixth section 26 is curved and extends between the two curved junctions.

Referring to FIG. 2, the second section 22 includes a first curved portion 221, a linear portion 224, a second curved portion 222, and a third curved portion 223, which are arranged in sequence in a direction pointing from the first section 21 to the third section 23 when viewed in the direction of the axis AX of the coil 20. The first curved portion 221 is curved outward in the radial direction of the coil 20. The linear portion 224 is parallel to the first end face 15. The second curved portion 222 is curved outward in the radial direction of the coil 20. The third curved portion 223 is curved inward in the radial direction of the coil 20. The first curved portion 221 is connected to the first section 21. The third curved portion 223 is connected to the third section 23. The boundary between the first curved portion 221 and the linear portion 224, the boundary between the linear portion 224 and the second curved portion 222, and the boundary between the second curved portion 222 and the third curved portion 223 are indicated by dotted lines in FIG. 2. Although thermal stress and/or bending stress can be exerted on the inductor component 1 during mounting, the second section 22 including the first curved portion 221, the second curved portion 222, and the third curved portion 223 can escape undue stress.

Likewise, the eighth section 28 includes a first curved portion 281, a linear portion 284, a second curved portion 282, and a third curved portion 283, which are arranged in sequence in a direction pointing from the first section 21 to the seventh section 27 when viewed in the direction of the axis AX of the coil 20. The first curved portion 281 is curved outward in the radial direction of the coil 20. The linear portion 284 is parallel to the first end face 15. The second curved portion 282 is curved outward in the radial direction of the coil 20. The third curved portion 283 is curved inward in the radial direction of the coil 20. The first curved portion 281 is connected to the first section 21. The third curved portion 283 is connected to the seventh section 27. The boundary between the first curved portion 281 and the linear portion 284, the boundary between the linear portion 284 and the second curved portion 282, and the boundary between the second curved portion 282 and the third curved portion 283 are indicated by dotted lines in FIG. 2. Although thermal stress and/or bending stress can be exerted on the inductor component 1 during mounting, the eighth section 28 including the first curved portion 281, the second curved portion 282, and the third curved portion 283 can escape undue stress.

Referring to FIG. 2, the coil 20 has left-right symmetry with respect to a straight line crossing the axis AX of the coil 20 and extending in the Z direction when viewed in the direction of the axis AX of the coil 20. The unevenness in the characteristics of the inductor component 1 can be reduced accordingly.

Specifically, the second section 22 and the eighth section 28 are symmetrically placed at the left and right of the straight line crossing the axis AX of the coil 20 and extending in the Z direction. The third section 23 and the seventh section 27 are symmetrically placed at the left and right of the straight line crossing the axis AX of the coil 20 and extending in the Z direction. The first section 21 has left-right symmetry with respect to the straight line crossing the axis AX of the coil 20 and extending in the Z direction. The fifth section 25 has left-right symmetry with respect to the straight line crossing the axis AX of the coil 20 and extending in the Z direction.

Referring to FIG. 2, part of the second section 22 extends to the third section 23 and in a direction forming an oblique angle with respect to the bottom face 17 when viewed in the direction of the axis AX. Specifically, the second curved portion 222 and the third curved portion 223 of the second section 22 extend in a direction forming an oblique angle with respect to the bottom face 17. The proportion of the bent portion in the coil 20 is reduced accordingly. This enables a reduction in signal reflection and, by extension, an increase in Q value.

Likewise, part of the eighth section 28 extends to the seventh section 27 and in a direction forming an oblique angle with respect to the bottom face 17 when viewed in the direction of the axis AX. Specifically, the second curved portion 282 and the third curved portion 283 of the eighth section 22 extend in a direction forming an oblique angle with respect to the bottom face 17. The proportion of the bent portion in the coil 20 is reduced accordingly. This enables a reduction in signal reflection and, by extension, an increase in Q value.

As illustrated in FIG. 2, the junction between the fourth section 24 and the fifth section 25 extend in a direction forming an oblique angle with respect to the bottom face 17 when viewed in the direction of the axis AX. Specifically, a line tangent to the junction between the fourth section 24 and the fifth section 25 extends in a direction forming an oblique angle with respect to the bottom face 17. The proportion of the bent portion in the coil 20 is reduced accordingly. This enables a reduction in signal reflection and, by extension, an increase in Q value.

Likewise, the junction between the fifth section 25 and the sixth section 26 extends in a direction forming an oblique angle with respect to the bottom face 17 when viewed in the direction of the axis AX. Specifically, a line tangent to the junction between the fifth section 25 and the sixth section 26 extends in a direction forming an oblique angle with respect to the bottom face 17. The proportion of the bent portion in the coil 20 is reduced accordingly. This enables a reduction in signal reflection and, by extension, an increase in Q value.

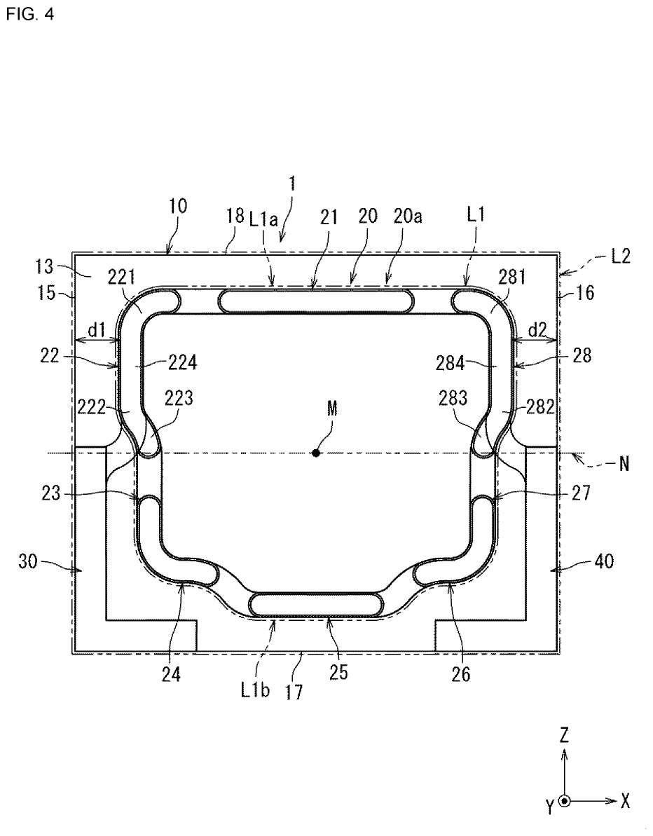

FIG. 4 is a front view of the inductor component 1 seen through the first side face 13 of the inductor component 1. The distance denoted by d1 in FIG. 4 is a first shortest distance between the second section 22 and the first end face 15 viewed in the direction of the axis AX of the coil 20. The first shortest distance d1 is preferably not less than 5 μm and not more than 28 μm (i.e., from 5 μm to 28 μm). The first shortest distance d1 in the present embodiment is the shortest distance between the linear portion 224 of the second section 22 and the first end face 15.

The distance denoted by d2 in FIG. 4 is a second shortest distance between the eighth section 28 and the second end face 16 viewed in the direction of the axis AX of the coil 20. The second shortest distance d2 is preferably not less than 5 μm and not more than 28 μm (i.e., from 5 μm to 28 μm). The second shortest distance d2 in the present embodiment is the shortest distance between the linear portion 284 of the eighth section 28 and the second end face 16. For example, the inductor component 1 is ground along the X-Y plane to expose a surface on which the first shortest distance d1 and the second shortest distance d2 is to be measured.

Setting the upper limit on the first shortest distance d1 and the second shortest distance d2 is effective at improving inductance characteristics and Q characteristics. Using glass as the material of the body 10 provides ease of checking whether the appearance of the coil 20 is proper. Setting the lower limit on the first shortest distance d1 and the second shortest distance d2 is effective at keeping the coil 20 from being exposed at the surface of the body 10. It is required that at least one of the first shortest distance d1 and the second shortest distance d2 be within the limits.

Referring to FIG. 4, L1 denotes the perimeter of the coil 20 viewed in the direction of the axis AX of the coil 20, and L2 denotes the perimeter of the body 10 viewed in the direction of the axis AX of the coil 20. The perimeter L1 of the coil 20 is preferably not less than 70% of the perimeter L2 of the body 10. Specifically, the perimeter L1 of the coil 20 is the perimeter of the winding portion 20a of the coil 20. The perimeter L2 of the body 10 is the perimeter of the shape defined by the top face 18, the bottom face 17, the first end face 15, and the second end face 16 of the body 10. For example, X-rays are projected onto the inductor component 1 in the Y direction to obtain a radiographic image based on which the perimeter L1 of the coil 20 is to be measured. The increase in the perimeter L1 of the coil 20 translates into an increase in the inner diameter of the coil 20. This yields an improvement in inductance characteristics and an improvement in Q characteristics.

In some embodiments, coil wiring layers 501 to 510 of the coil 20 each have more than one turn such that the winding portion 20a in a radiographic view of the coil 20 irradiated with X-rays in the Y direction has more than one perimeter. In this case, the perimeter formed by joining the outermost edges of the winding portion 20a is regarded as the perimeter L1.

With two portions being adjacent to each other with a center point M of the body 10 therebetween and constituting the coil 20 viewed in the direction of the axis AX, L1a denotes the perimeter of one of the portions that is closer to the top face 18 than to the bottom face 17, and Lib denotes the perimeter of the other portion closer to the bottom face 17 than to the top face 18. The top-face-side perimeter L1a is preferably not less than 105% of the bottom-face-side perimeter L1b.

The center point M of the body 10 in the present embodiment is the center of gravity of the body 10 or, more specifically, the center of gravity of the first side face 13 of the body 10 viewed in the direction of the axis AX of the coil 20. The coil 20 is composed of two portions that are located on opposite sides of a center line N, which passes through the center point M of the body 10 and extends in the X direction. The top-face-side perimeter L1a is part of the perimeter L1 of the coil 20 or, more specifically, the perimeter of one of the portions that is closer to the top face 18 than to the bottom face 17, and the bottom-face-side perimeter L1b is part of the perimeter L1 of the coil 20 or, more specifically, the perimeter of the other portion closer to the bottom face 17 than to the top face 18.

The coil 20 is designed as above such that the center of gravity of the coil 20 is shifted away from the center point M of the body 10 and toward the top face 18. The center of gravity of the first outer electrode 30 and the center of gravity of the second outer electrode 40 are each closer than the center point M of the body 10 to the bottom face 17, and the center of gravity of the coil 20 is closer than the center point M of the body 10 to the top face 18. As a result, the center of gravity of the inductor component 1 is in the near-by area surrounding the center point M of the body 10. Accordingly, the inductor component 1 has increased portability.

Referring to FIGS. 3A and 3B, the coil 20 includes coil wiring layers respectively denoted by 501 to 510 and via wiring layers respectively denoted by 601 to 609. The coil wiring layers 501 to 510 are arranged in a stack in the direction of the axis AX. The via wiring layers 601 to 609 are each located between two coil wiring layers superposed with no other coil wiring layers therebetween in the direction of the axis AX and form a connection between the two respective coil wiring layers superposed with no other coil wiring layers therebetween in the direction of the axis AX. The coil wiring layers 501 to 510 are provided on the respective insulating layers 11. Likewise, the via wiring layers 601 to 609 are provided in the respective insulating layers 11.

The coil wiring layers 501 to 510 are wound in the respective planes and are connected in series with each other to constitute a helix. The coil wiring layers 501 to 510 are wound on main surfaces (X-Z planes) of the respective insulating layers 11, with the main surfaces being orthogonal to the direction of the axis AX (the Y direction). The number of turns in each of the coil wiring layers 501 to 510 is less than one. In some embodiments, however, the number of turns in each of the coil wiring layers 501 to 510 is greater than or equal to one.

The via wiring layers 601 to 609 extend through the respective insulating layers 11 in the thickness direction (the Y direction). The coil wiring layers superposed with no other coil wiring layers therebetween in the direction in which the layers are stacked are electrically connected in series with each other by the via wiring layer disposed therebetween. The coil wiring layers 501 to 510 are electrically connected in series with each other in this fashion to constitute a helix.

Specifically, the first coil wiring layer 501, the second coil wiring layer 502, the third coil wiring layer 503, the fourth coil wiring layer 504, the fifth coil wiring layer 505, the sixth coil wiring layer 506, the seventh coil wiring layer 507, the eighth coil wiring layer 508, the ninth coil wiring layer 509, and the tenth coil wiring layer 510 are stacked in sequence in the Y direction. The first coil wiring layer 501 has an end connected to one of the first outer electrode conductor layers 33 of the first outer electrode 30. The tenth coil wiring layer 510 has an end connected to one of the second outer electrode conductor layers 43 of the second outer electrode 40.

The first via wiring layer 601 is disposed between the first coil wiring layer 501 and the second coil wiring layer 502 to form a connection between an end portion of the first coil wiring layer 501 and an end portion of the second coil wiring layer 502. The second via wiring layer 602 is disposed between the second coil wiring layer 502 and the third coil wiring layer 503 to form a connection between an end portion of the second coil wiring layer 502 and an end portion of the third coil wiring layer 503. The third via wiring layer 603 is disposed between the third coil wiring layer 503 and the fourth coil wiring layer 504 to form a connection between an end portion of the third coil wiring layer 503 and an end portion of the fourth coil wiring layer 504. The fourth via wiring layer 604 is disposed between the fourth coil wiring layer 504 and the fifth coil wiring layer 505 to form a connection between an end portion of the fourth coil wiring layer 504 and an end portion of the fifth coil wiring layer 505. The fifth via wiring layer 605 is disposed between the fifth coil wiring layer 505 and the sixth coil wiring layer 506 to form a connection between an end portion of the fifth coil wiring layer 505 and an end portion of the sixth coil wiring layer 506.

The sixth via wiring layer 606 is disposed between the sixth coil wiring layer 506 and the seventh coil wiring layer 507 to form a connection between an end portion of the sixth coil wiring layer 506 and an end portion of the seventh coil wiring layer 507. The seventh via wiring layer 607 is disposed between the seventh coil wiring layer 507 and the eighth coil wiring layer 508 to form a connection between an end portion of the seventh coil wiring layer 507 and an end portion of the eighth coil wiring layer 508. The eighth via wiring layer 608 is disposed between the eighth coil wiring layer 508 and the ninth coil wiring layer 509 to form a connection between an end portion of the eighth coil wiring layer 508 and an end portion of the ninth coil wiring layer 509. The ninth via wiring layer 609 is disposed between the ninth coil wiring layer 509 and the tenth coil wiring layer 510 to form a connection between an end portion of the ninth coil wiring layer 509 and an end portion of the tenth coil wiring layer 510.

As illustrated FIGS. 3A, 3B, and 4, at least one of the via wiring layers 601 to 609 has a shape corresponding to the second section 22 when viewed in the direction of the axis AX. Specifically, the sixth via wiring layer 606 has a shape corresponding to the second section 22. When viewed in the direction of the axis AX, the sixth via wiring layer 606 includes a first curved portion 606a, a linear portion 606d, a second curved portion 606b, and a third curved portion 606c. The first curved portion 606a corresponds to the first curved portion 221 of the second section 22. The linear portion 606d corresponds to the linear portion 224 of the second section 22. The second curved portion 606b corresponds to the second curved portion 222 of the second section 22. The third curved portion 606c corresponds to the third curved portion 223 of the second section 22.

Although thermal stress and/or bending stress can be exerted on the inductor component 1 during mounting, the sixth via wiring layer 606 can escape undue stress due to the fact that the sixth via wiring layer 606 has a shape corresponding to the second section 22 and includes the first curved portion 606a, the second curved portion 606b, and the third curved portion 606c when viewed in the direction of the axis AX.

Likewise, at least one of the via wiring layers 601 to 609 has a shape corresponding to the eighth section 28 when viewed in the direction of the axis AX. Specifically, the fourth via wiring layer 604 has a shape corresponding to the eighth section 28. When viewed in the direction of the axis AX, the fourth via wiring layer 604 includes a first curved portion 604a, a linear portion 604d, a second curved portion 604b, and a third curved portion 604c. The first curved portion 604a corresponds to the first curved portion 281 of the eighth section 28. The linear portion 604d corresponds to the linear portion 284 of the eighth section 28. The second curved portion 604b corresponds to the second curved portion 282 of the eighth section 28. The third curved portion 604c corresponds to the third curved portion 283 of the eighth section 28.

Although thermal stress and/or bending stress can be exerted on the inductor component 1 during mounting, the fourth via wiring layer 604 can escape undue stress due to the fact that the fourth via wiring layer 604 has a shape corresponding to the eighth section 28 and includes the first curved portion 604a, the second curved portion 604b, and the third curved portion 604c when viewed in the direction of the axis AX.

As illustrated in FIGS. 3A, 3B, and 4, the first to tenth coil wiring layers respectively denoted by 501 to 510 each overlap the first to eighth sections respectively denoted by 21 to 28 when viewed in the direction of the axis AX. The fifth via wiring layer 605 geometrically corresponds to the first section 21 when viewed in the direction of the axis AX. The sixth via wiring layer 606 geometrically corresponds to the second section 22 when viewed in the direction of the axis AX. The first via wiring layer 601 and the seventh via wiring layer 607 each geometrically correspond to the third section 23 and the fourth section 24 when viewed in the direction of the axis AX. The second via wiring layer 602 and the eight via wiring layer 608 each geometrically correspond to the fifth section 25 when viewed in the direction of the axis AX. The third via wiring layer 603 and the ninth via wiring layer 609 each geometrically correspond to the sixth section 26 and the seventh section 27 when viewed in the direction of the axis AX. The fourth via wiring layer 604 geometrically corresponds to the eighth section 28 when viewed in the direction of the axis AX.

That is, the first section 21 includes part of each of the first to tenth coil wiring layers respectively denoted by 501 to 510 and the fifth via wiring layer 605. The second section 22 includes part of each of the first to tenth coil wiring layers respectively denoted by 501 to 510 and the sixth via wiring layer 606. The third section 23 includes part of each of the first to tenth coil wiring layers respectively denoted by 501 to 510, part of the first via wiring layer 601, and part of the seventh via wiring layer 607. The fourth section 24 includes part of each of the first to tenth coil wiring layers respectively denoted by 501 to 510, part of the first via wiring layer 601, and part of the seventh via wiring layer 607. The fifth section 25 includes part of each of the first to tenth coil wiring layers respectively denoted by 501 to 510, the second via wiring layer 602, and the eighth via wiring layer 608. The sixth section 26 includes part of each of the first to tenth coil wiring layers respectively denoted by 501 to 510, part of the third via wiring layer 603, and part of the ninth via wiring layer 609. The seventh section 27 includes part of each of the first to tenth coil wiring layers respectively denoted by 501 to 510, part of the third via wiring layer 603, and part of the ninth via wiring layer 609. The eighth section 28 includes part of each of the first to tenth coil wiring layers respectively denoted by 501 to 510 and the fourth via wiring layer 604. The first to eighth section respectively denote by 21 to 28 may each include any part of each of the coil wiring layers 501 to 510 and any part of the via wiring layers 601 to 609.

The following describes a procedure for producing the inductor component 1.

The first to tenth coil wiring layers respectively denoted by 501 to 510 and the first to ninth via wiring layers respectively denoted by 601 to 609 as well as the insulating layers 11 are alternately stacked on one another in the direction pointing from top to bottom in FIGS. 3A and 3B, whereby the inductor component 1 is obtained. The coil wiring layers 501 to 510 are formed on the respective insulating layers 11 by, for example, screen printing. Cavities may be formed in the insulating layers 11 by photolithography or laser technology before the via wiring layers 601 to 609 are formed in the cavities by, for example, screen printing.

### Second Embodiment

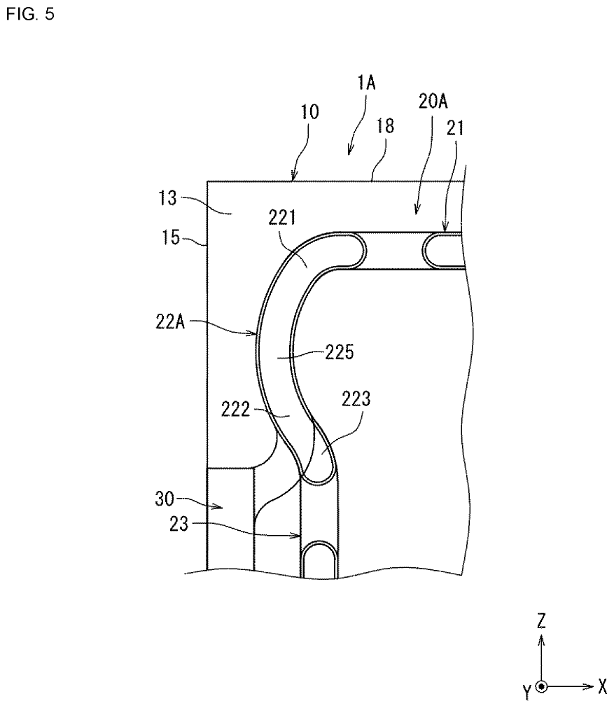

FIG. 5 is an enlarged front view of part of an inductor component according to a second embodiment, with the inductor component seen through a first side face of the inductor component. The difference between the first embodiment and the second embodiment is in the shape of the second section of the coil as will be described below. Each element in the first embodiment and the corresponding element in the second embodiment are denoted by the same reference sign and will not be further elaborated on here.

Referring to FIG. 5, the inductor component according to the second embodiment is denoted by 1A and includes a coil 20A. The coil 20A includes a second section 22A, which is curved when viewed in the direction of the axis AX of the coil 20A (i.e., a direction orthogonal to the first side face 13). Specifically, the second section 22A, unlike the linear portion 224 of the second section 22 in the first embodiment, does not include the linear portion 224. Instead, the second section 22A in the second embodiment includes a fourth curved part 225. The fourth curved part 225 is curved outward in the radial direction of the coil 20A. For example, the radius of curvature of the fourth curved part 225 is equal to the radius of curvature on both sides of it, in which case the fourth curved part 225, the first curved portion 221, and the second curved portion 222 may constitute an arc.

Although thermal stress and/or bending stress can be exerted on the inductor component 1A during mounting, the second section 22A including no linear portion can escape undue stress. As with the second section 22A, the eighth section may be curved. That is, the eighth section, unlike the eighth section in the first embodiment, does not include a linear portion. Instead, the eighth section in the second embodiment is curved outward in the radial direction of the coil. The eighth section including no linear portion can escape undue stress. At least one of the second section, the fourth section, the sixth section, and the eighth section may be curved.

The present disclosure is not limited to the embodiments described above, and design changes may be made within a range not departing from the spirit of the present disclosure. For example, the features of the first embodiment and the features of the second embodiment may be implemented in various combinations. The number of coil wiring layers may be increased or decreased. Likewise, the number of the via wiring layers may be increased or decreased. The first to eighth sections each may include a linear portion or may be entirely curved.

The following aspects are disclosed herein.

<1> An inductor component including a body; a coil disposed in the body and helically wound around an axis; and a first outer electrode and a second outer electrode that are provided to the body and electrically connected to the coil. The body has a first end face and a second end face on opposite sides, a first side face and a second side face on opposite sides, a bottom face connected between the first end face and the second end face and between the first side face and the second side face, and a top face on an opposite side from the bottom face. The first outer electrode includes a first end face portion extending along the first end face and a first bottom face portion connected to the first end face portion and extending along the bottom face. The second outer electrode includes a second end face portion extending along the second end face and a second bottom face portion connected to the second end face portion and extending along the bottom face. The axis is parallel to the bottom face and forms an angle with respect to the first side face and the second side face. The coil viewed in a direction of the axis includes a first section facing the top face, a second section facing the first end face, a third section facing the first end face portion, a fourth section facing the first bottom face portion, a fifth section facing the bottom face, a sixth section facing the second bottom face portion, a seventh section facing the second end face portion, and an eighth section facing the second end face. The first section, the second section, the third section, the fourth section, the fifth section, the sixth section, the seventh section, and the eighth section are arranged in sequence in a circular fashion when viewed in the direction of the axis. The second section is closer than the third section to the first end face when viewed in the direction of the axis. The eighth section is closer than the seventh section to the second end face when viewed in the direction of the axis. The fifth section is closer than the fourth section and the sixth section to the bottom face when viewed in the direction of the axis.

<2> The inductor component according to <1>, wherein the first section, the third section, the fifth section, and the seventh section each include a linear portion when viewed in the direction of the axis.

<3> The inductor component according to <1> or <2>, wherein at least one of the second section, the fourth section, the sixth section, or the eighth section is curved when viewed in the direction of the axis.

<4> The inductor component according to any one of <1> to <3>, wherein a first shortest distance between the second section and the first end face viewed in the direction of the axis is not less than 5 μm and not more than 28 μm (i.e., from 5 μm to 28 μm). Also, a second shortest distance between the eighth section and the second end face viewed in the direction of the axis is not less than 5 μm and not more than 28 μm (i.e., from 5 μm to 28 μm).

<5> The inductor component according to any one of <1> to <4>, wherein a perimeter of the coil viewed in the direction of the axis is not less than 70% of a perimeter of the body viewed in the direction of the axis. Also, with two portions being adjacent to each other with a center point of the body therebetween and constituting the coil viewed in the direction of the axis, a perimeter of one of the portions that is closer to the top face than to the bottom face is not less than 105% of a perimeter of the other portion closer to the bottom face than to the top face.

<6> The inductor component according to any one of <1> to <5>, wherein the second section viewed in the direction of the axis includes a first curved portion, a linear portion, a second curved portion, and a third curved portion that are arranged in sequence in a direction pointing from the first section to the third section. The first curved portion is curved outward in a radial direction of the coil, the linear portion is parallel to the first end face, the second curved portion is curved outward in the radial direction of the coil, and the third curved portion is curved inward in the radial direction of the coil.

<7> The inductor component according to <6>, wherein the coil includes coil wiring layers arranged in a stack in the direction of the axis and via wiring layers each connected between the two respective coil wiring layers superposed with no other coil wiring layers therebetween in the direction of the axis. Also, at least one of the via wiring layers has a shape corresponding to the second section when viewed in the direction of the axis.

<8> The inductor component according to any one of <1> to <7>, wherein part of the second section extends to the third section and in a direction forming an oblique angle with respect to the bottom face when viewed in the direction of the axis.

<9> The inductor component according to any one of <1> to <8>, wherein a boundary between the fourth section and the fifth section viewed in the direction of the axis forms an oblique angle with respect to the bottom face.

<10> An inductor component including a body; a coil disposed in the body and helically wound around an axis; and a first outer electrode and a second outer electrode that are provided to the body and electrically connected to the coil. The body has a first end face and a second end face on opposite sides, a first side face and a second side face on opposite sides, a bottom face connected between the first end face and the second end face and between the first side face and the second side face, and a top face on an opposite side from the bottom face. The first outer electrode includes a first end face portion extending along the first end face and a first bottom face portion connected to the first end face portion and extending along the bottom face. The axis is parallel to the bottom face and forms an angle with respect to the first side face and the second side face. The coil viewed in a direction of the axis includes a first section facing the top face, a second section facing the first end face, a third section facing the first end face portion, and a fourth section facing the first bottom face portion. The second section is closer than the third section to the first end face when viewed in the direction of the axis.

What is claimed is:

1. An inductor component comprising:
a body;
a coil in the body and helically wound around an axis; and
a first outer electrode and a second outer electrode that are at the body and electrically connected to the coil, wherein
the body has a first end face and a second end face on opposite sides, a first side face and a second side face on opposite sides, a bottom face connected between the first end face and the second end face and between the first side face and the second side face, and a top face on an opposite side from the bottom face,
the first outer electrode includes a first end face portion extending along the first end face and a first bottom face portion connected to the first end face portion and extending along the bottom face,
the second outer electrode includes a second end face portion extending along the second end face and a second bottom face portion connected to the second end face portion and extending along the bottom face,
the axis is parallel to the bottom face and intersects the first side face and the second side face,
the coil viewed in a direction of the axis includes a first section facing the top face, a second section facing the first end face, a third section facing the first end face portion, a fourth section facing the first bottom face portion, a fifth section facing the bottom face, a sixth section facing the second bottom face portion, a seventh section facing the second end face portion, and an eighth section facing the second end face,
the first section, the second section, the third section, the fourth section, the fifth section, the sixth section, the seventh section, and the eighth section are in sequence in a circular fashion when viewed in the direction of the axis,
the second section is closer to the first end face than the third section when viewed in the direction of the axis,
the eighth section is closer to the second end face than the seventh section when viewed in the direction of the axis, and
the fifth section is closer to the bottom face than the fourth section and the sixth section when viewed in the direction of the axis.

2. The inductor component according to claim 1, wherein
the first section, the third section, the fifth section, and the seventh section each include a linear portion when viewed in the direction of the axis.

3. The inductor component according to claim 1, wherein
at least one of the second section, the fourth section, the sixth section, or the eighth section is curved when viewed in the direction of the axis.

4. The inductor component according to claim 1, wherein
a first shortest distance between the second section and the first end face viewed in the direction of the axis is from 5 μm to 28 μm, and
a second shortest distance between the eighth section and the second end face viewed in the direction of the axis is from 5 μm to 28 μm.

5. The inductor component according to claim 1, wherein
a perimeter of the coil viewed in the direction of the axis is 70% or greater of a perimeter of the body viewed in the direction of the axis, and
with two portions being adjacent to each other with a center point of the body therebetween and configuring the coil viewed in the direction of the axis, a perimeter of one of the two portions that is closer to the top face than to the bottom face is 105% or greater of a perimeter of the other portion closer to the bottom face than to the top face.

6. The inductor component according to claim 1, wherein
the second section viewed in the direction of the axis includes a first curved portion, a linear portion, a second curved portion, and a third curved portion that are in sequence from the first section toward the third section,
the first curved portion is curved outward in a radial direction of the coil,
the linear portion is parallel to the first end face,
the second curved portion is curved outward in the radial direction of the coil, and
the third curved portion is curved inward in the radial direction of the coil.

7. The inductor component according to claim 6, wherein
the coil includes coil wiring layers stacked in the direction of the axis and via wiring layers connecting the two coil wiring layers adjacent to each other in the direction of the axis, and
at least one of the via wiring layers has a shape corresponding to the second section when viewed in the direction of the axis.

8. The inductor component according to claim 1, wherein
the second section includes a portion extending to the third section and extending obliquely with respect to the bottom face when viewed in the direction of the axis.

9. The inductor component according to claim 1, wherein
a boundary between the fourth section and the fifth section defines an oblique angle with respect to the bottom face when viewed in the direction of the axis.

10. The inductor component according to claim 2, wherein
at least one of the second section, the fourth section, the sixth section, or the eighth section is curved when viewed in the direction of the axis.

11. The inductor component according to claim 2, wherein
a first shortest distance between the second section and the first end face viewed in the direction of the axis is from 5 μm to 28 μm, and
a second shortest distance between the eighth section and the second end face viewed in the direction of the axis is from 5 μm to 28 μm.

12. The inductor component according to claim 2, wherein
a perimeter of the coil viewed in the direction of the axis is 70% or greater of a perimeter of the body viewed in the direction of the axis, and
with two portions being adjacent to each other with a center point of the body therebetween and configuring the coil viewed in the direction of the axis, a perimeter of one of the two portions that is closer to the top face than to the bottom face is 105% or greater of a perimeter of the other portion closer to the bottom face than to the top face.

13. The inductor component according to claim 2, wherein
the second section viewed in the direction of the axis includes a first curved portion, a linear portion, a second curved portion, and a third curved portion that are in sequence from the first section toward the third section,
the first curved portion is curved outward in a radial direction of the coil,
the linear portion is parallel to the first end face,
the second curved portion is curved outward in the radial direction of the coil, and
the third curved portion is curved inward in the radial direction of the coil.

14. The inductor component according to claim 13, wherein
the coil includes coil wiring layers stacked in the direction of the axis and via wiring layers connecting the two coil wiring layers adjacent to each other in the direction of the axis, and
at least one of the via wiring layers has a shape corresponding to the second section when viewed in the direction of the axis.

15. The inductor component according to claim 2, wherein
the second section includes a portion extending to the third section and extending obliquely with respect to the bottom face when viewed in the direction of the axis.

16. The inductor component according to claim 2, wherein
a boundary between the fourth section and the fifth section defines an oblique angle with respect to the bottom face when viewed in the direction of the axis.
